(19) United States
(12) Patent Application Publication
(10) Pub. No.: US 2026/0289063 A1
(43) Pub. Date: Sep. 24, 2026

(54) OPTIMIZATION METHOD, OPTIMIZATION APPARATUS, ELECTRONIC DEVICE, STORAGE MEDIUM AND PROGRAM PRODUCT

(71) Applicant: GigaDevice Semiconductor Inc., Beijing (CN)

(72) Inventors: Linyang Li, Beijing (CN); Xuliang Qi, Beijing (CN); Hui Qu, Beijing (CN)

(21) Appl. No.: 19/425,143

(22) Filed: Dec. 18, 2025

(30) Foreign Application Priority Data
Mar. 21, 2025 (CN) 2025103450770

(51) Int. Cl. G06F 30/392; G06F 30/398; H03M 1/78

(52) U.S. Cl. CPC G06F 30/392; G06F 30/398; H03M 1/785

(57) ABSTRACT

A method for optimizing an arrangement of a resistor array, includes: creating a resistor array based on a conversion circuit of a digital-to-analog converter; establishing a mapping relationship between a layout resistor in the resistor array and a circuit resistor in the conversion circuit, the layout resistor having a simulated resistance value, the mapping relationship being used to determine a resistance value of the circuit resistor based on the layout resistor and the corresponding simulated resistance value; constructing a performance model of the digital-to-analog converter based on the mapping relationship; and performing iterative evolution on the mapping relationship based on the performance model until a target mapping relationship is obtained by evolution.

### CROSS REFERENCE TO RELATED APPLICATIONS

The present disclosure claims priority to Chinese Patent Application No. 202510345077.0 entitled “Optimization method, optimization apparatus, electronic device, storage medium and program product”, filed on Mar. 21, 2025, and the entire contents of which are incorporated herein by reference.

### TECHNICAL FIELD

The present disclosure relates to the field of semiconductor technology, and in particular to a method for optimizing an arrangement of a resistor array, an apparatus for optimizing an arrangement of a resistor array, an electronic device, a computer-readable storage medium, and a computer program product.

### BACKGROUND

As the size of the integrated circuit is reduced, more functional units can be integrated on the chip. As a bridge connecting digital signals and analog signals, the digital-to-analog converter (DAC) also needs to have higher accuracy to be better integrated into the highly integrated system environment. Among them, the adaptability between the switch and the resistor array in the DAC is a main factor affecting the DAC accuracy. Therefore, the arrangement of the resistor array needs to be optimized to improve the adaptability.

It should be noted that the information disclosed in the above background part is only used to enhance the understanding of the background of the present disclosure, and therefore may include information that does not constitute the related art known to those of ordinary skill in the art.

### SUMMARY

According to an aspect of the present disclosure, there is provided a method for optimizing an arrangement of a resistor array, including: creating a corresponding resistor array based on a conversion circuit of a digital-to-analog converter; establishing a mapping relationship between a layout resistor in the resistor array and a circuit resistor in the conversion circuit, wherein the layout resistor has a simulated resistance value, and the mapping relationship is used to determine a resistance value of the circuit resistor based on the layout resistor and the corresponding simulated resistance value; constructing a performance model of the digital-to-analog converter based on the mapping relationship; and performing iterative evolution on the mapping relationship based on the performance model until a target mapping relationship is obtained by evolution, wherein the target mapping relationship is used to determine a target arrangement of the layout resistor in the resistor array, to determine a target resistance value of the circuit resistor based on the target arrangement, and enable the performance model to output a target performance parameter based on the target resistance value.

According to another aspect of the present disclosure, there is provided an electronic device, including: a processor; and a memory, configured to store an executable instruction by the processor; where the processor is configured to perform the method for optimizing the arrangement of the resistor array in the first aspect by executing the executable instruction.

According to another aspect of the present disclosure, there is provided a non-transitory computer-readable storage medium, and a computer program is stored on the non-transitory computer-readable storage medium. When the computer program is executed by a processor, the method for optimizing the arrangement of the resistor array is implemented.

It is to be understood that the foregoing general description and the following detailed description are exemplary and explanatory only and are not restrictive of the present disclosure.

### BRIEF DESCRIPTION OF THE DRAWINGS

The accompanying drawings here, which are incorporated into the description and constitute a part of the description, illustrate embodiments consistent with the present disclosure, and together with the description serve to explain the principles of the present disclosure. Obviously, the accompanying drawings described below are only some embodiments of the present disclosure. For those of ordinary skill in the art, other accompanying drawings can also be obtained based on these accompanying drawings without creative efforts.

FIG. 1 shows a schematic flow chart of a method for optimizing an arrangement of a resistor array according to an embodiment of the present disclosure;

FIG. 2 shows a schematic diagram a conversion circuit of a digital-to-analog converter according to an embodiment of the present disclosure;

FIG. 3 shows a schematic flow chart of another method for optimizing an arrangement of a resistor array according to an embodiment of the present disclosure;

FIG. 4 shows a schematic diagram of performing a test on a layout resistor in a resistor array according to an embodiment of the present disclosure;

FIG. 5 shows a schematic diagram of a single layout resistor when there is a one-to-one relationship between the circuit resistor and the layout resistor according to an embodiment of the present disclosure;

FIG. 6 shows a schematic diagram of two layout resistors when there is a one-to-two relationship between the circuit resistor and the layout resistor according to an embodiment of the present disclosure;

FIG. 7 shows a schematic flow chart of another method for optimizing an arrangement of a resistor array according to an embodiment of the present disclosure;

FIG. 8 shows a schematic flow chart of another method for optimizing an arrangement of a resistor array according to an embodiment of the present disclosure;

FIG. 9 shows a schematic diagram of another conversion circuit of a digital-to-analog converter according to an embodiment of the present disclosure;

FIG. 10 shows a schematic diagram of a relationship curve between DNL values and the number of iterative evolutions according to an embodiment of the present disclosure;

FIG. 11 shows a schematic diagram of another conversion circuit of a digital-to-analog converter according to an embodiment of the present disclosure;

FIG. 12 shows a schematic diagram of another relationship curve between DNL values and the number of iterative evolutions according to an embodiment of the present disclosure;

FIG. 13 shows a schematic diagram of an apparatus for optimizing an arrangement of a resistor array according to an embodiment of the present disclosure;

FIG. 14 shows a structural block diagram of an electronic device according to an embodiment of the present disclosure.

### DETAILED DESCRIPTION

Example embodiments will now be described more fully with reference to the accompanying drawings. However, example embodiments can be implemented in a variety of forms and should not be construed as limited to the examples set forth here; by contrast, these embodiments are provided so that the present disclosure will be more comprehensive and complete and the concepts of the example embodiments will be fully conveyed to those skilled in the art. The described features, structures, or characteristics may be combined in any suitable manner in one or more embodiments.

In addition, the accompanying drawings are only schematic illustrations of the present disclosure and are not necessarily drawn to scale. The same reference numerals in the drawings represent the same or similar parts, and repeated description of them will be omitted. Some of the block diagrams shown in the accompanying drawings are functional entities and do not necessarily correspond to physically or logically independent entities. These functional entities may be implemented in software form, or implemented in one or more hardware modules or integrated circuits, or implemented in different networks and/or processor apparatuses and/or microcontroller apparatuses.

As the size of the integrated circuit is reduced, the digital-to-analog converter (DAC), as a bridge connecting digital signals and analog signals, is an important part of many electronic devices. Therefore, the performance of the DAC also affects the performance of the electronic devices that use the DAC. There are many component architectures for DAC, including weighted resistor array structure and R-2R ladder resistor array structure, where the R-2R ladder resistor array structure is widely used due to its small area and fast switching speed.

In some embodiments, during the actual manufacturing process of the DAC, since the electrical environment around the resistors in the resistor array may affect their resistance values, the layout resistors in the resistor array may have different resistance values when they are in different positions, further causing that there are different adaptabilities between the R-2R resistor array and the switch. Therefore, it is needed to optimize the arrangement of the resistor array to improve the adaptability between the switch and the R-2R resistor array, so as to further improve the switching speed of the switch. In addition, for optimization of the arrangement of the resistor array, it is also needed to avoid the increase of the layout area to affect the resolution, differential nonlinear (DNL) and other performance of the DAC.

Therefore, there is an urgent need for an optimization of the arrangement of the resistor array to quantitatively optimize the arrangement of the resistor array, so as to better guide the design and application of the DAC. The purpose of the present disclosure is to provide a method for optimizing an arrangement of a resistor array, an apparatus for optimizing an arrangement of a resistor array, an electronic device, a computer-readable storage medium and a computer program product, so as to overcome, at least to a certain extent, the problem in the related art that the accuracy of the DAC is affected due to the insufficient adaptability between the switch and the resistor array.

In the embodiments of the present disclosure, through the solution of arrangement optimization and the resistor array modeling based on the genetic algorithm, the matching degree of different resistor arrays may be quantitatively and accurately analyzed, and the optimal arrangement for performance may be obtained quickly and efficiently. In the optimization solution, the matching of the resistors between rows in the resistor array may be comprehensively considered, and the optimization solution may be applied to poly resistor arrays and other resistor arrays, with fewer restrictions on the size and arrangement of the resistors.

To facilitate understanding, several terms involved in the present application are first explained below.

Differential nonlinearity (DNL) refers to that an ideal unit voltage VLSB is subtracted from the difference between analog output voltages corresponding to any two adjacent input digital codes.

Genetic algorithm (GA) is an optimization algorithm inspired by the principles of natural selection and genetics, which is used to find the optimal solution or the approximate optimal solution in a complex search space. Genetic algorithm simulates the inheritance, mutation and natural selection mechanisms in the process of biological evolution.

Fitness is a key concept in the genetic algorithm, which is used to measure the fitness of each individual (i.e., the solution to the problem) to the environment, that is, the degree of superiority or inferiority of the individual in solving the problem.

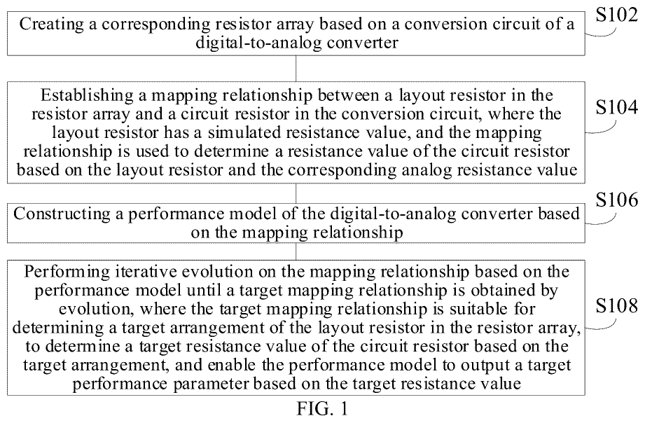

FIG. 1 shows a flow chart of a method for optimizing an arrangement of a resistor array according to an embodiment of the present disclosure.

As shown in FIG. 1, the method for optimizing the arrangement of the resistor array according to an embodiment of the present disclosure includes following steps.

In step S102, a corresponding resistor array is created based on a conversion circuit of a digital-to-analog converter.

In some embodiments, creating the corresponding resistor array based on the conversion circuit of the digital-to-analog converter includes: creating the resistor array based on the number of resistors in the conversion circuit, the configured number of rows in the array, the resistor process, and the resistor size.

In some embodiments, the layout resistor includes at least one of a polysilicon resistor, a metal resistor, and a thin film resistor.

In some embodiments, the total number of resistors in the resistor array depends on the number of resistors in the conversion circuit, so as to meet the requirements of different digital signal conversions for the number of resistors. The configured number of rows in the array is used to plan the arrangement of resistors on the circuit layout, thus affecting the interaction between the signal transmission path and the resistors. The resistor process (such as polysilicon, metal, and thin film resistor processes) provides the resistors with different basic electrical properties. The resistor size directly affects the resistor's electrical indicators, such as the resistance value, the parasitic parameter, etc.

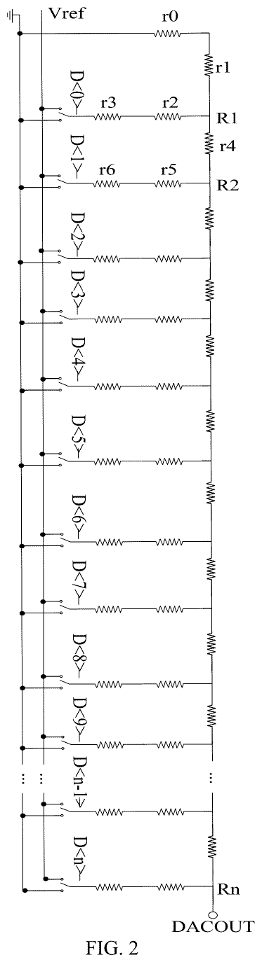

FIG. 2 shows a circuit diagram of a conversion circuit according to the present disclosure. As shown in FIG. 2, the conversion circuit includes n groups of resistors. Each group corresponding to an R-2R combination, for example, R1 corresponds to r1−(r2+r3), and R2 corresponds to r4−(r5+r6), etc. Each group corresponds to a 1-bit digital signal (1 or 0), and is used to control a group of switch signals, i.e., one of D<0> to D<n>, to convert different digital signals into corresponding analog signals.

In some embodiments, as shown in FIG. 2, the conversion circuit includes a circuit resistor r0, which is the resistor farthest from the DACOUT node. In the corresponding DAC resistor array, the circuit resistor r0 corresponds to the <F> bit, and the other D<n> corresponds to 3 circuit resistors. That is, the <F> bit does not correspond to a switch signal, but only indicates the position. For example, D<0> corresponds to r1~r3. During the initial mapping, the <F> bit and the digital signal control bits D<0> to D<n> may be arranged arbitrarily.

In some embodiments, there is an <F> bit before the D<0> bit of the conversion circuit, to correspond to the circuit resistor r0.

In the following embodiments, the initial resistor array is arranged in ascending order of D<0> to D<n>, where the <F> bit corresponding to r0 can be placed at the first bit or at a non-first bit.

In some embodiments, the <F> bit may be placed at any bit other than the first bit and the last bit. In this case, the D<0> at the first bit corresponds to r1 to r3, therefore, r1 corresponds to the first POLY. That is, when there is a one-to-one relationship between the circuit resistor and the layout resistor, r1=poly0; or, when there is a one-to-two relationship between the circuit resistor and the layout resistor, r1=poly0+poly1.

In step S104, a mapping relationship between a layout resistor in the resistor array and a circuit resistor in the conversion circuit is established, where the layout resistor has a simulated resistance value, and the mapping relationship is used to determine the resistance value of the circuit resistor based on the layout resistor and the corresponding simulated resistance value.

In some embodiments, the layout resistor refers to a resistor presented on the chip layout, which has properties of actual physical position, shape, and size, etc., while the circuit resistor may be understood as a resistance element represented in the circuit principle diagram.

In some embodiments, the mapping relationship refers to the positional correspondence between the layout resistor in the resistor array and the circuit resistor in the conversion circuit. By using the mapping relationship, a correspondence between the physical property of the layout resistor and the electrical function of the circuit resistor may be established. It may be understood that the circuit resistor and its position and connection relationship in the circuit are fixed. The mapping relationship may be adjusted by adjusting the position of the layout resistor in the resistor array, so as to achieve optimization the arrangement of the resistor array.

In some embodiments, due to limitations of the manufacturing process and adjustments to the connection method, even if the layout resistors are designed to have the same resistance value, the presented resistance values of the layout resistors at different positions of the resistor array are different. The simulated resistance value may be understood as a simulation of change in the actual resistance value. After the position of the layout resistor in the resistor array is determined, the simulated resistance value of the resistor may be determined. The simulated resistance value is mapped into the circuit based on the mapping relationship, and it is the resistance value of the circuit resistor.

In step S106, a performance model of the digital-to-analog converter is constructed based on the mapping relationship.

In some embodiments, the performance indicators of the digital-to-analog converter include resolution, accuracy, offset error, gain error, differential nonlinear error (DNL) and integrated nonlinearity error, etc.

In some embodiments, the input values of the performance model include the resistance value of the circuit resistor and the digital signal received by the digital-to-analog converter, and the input value is any one of the above performance indicators, where the resistance value of the circuit resistor is determined based on the mapping relationship between the layout resistor and the circuit resistor as well as the simulated resistance value of the layout resistor.

In step S108, iterative evolution is performed on the mapping relationship based on the performance model until a target mapping relationship is obtained by evolution, where the target mapping relationship is suitable for determining a target arrangement of the layout resistor in the resistor array, to determine a target resistance value of the circuit resistor based on the target arrangement, and enable the performance model to output a target performance parameter based on the target resistance value.

In some embodiments, the target mapping relationship refers to the obtained and optimized mapping relationship between the layout resistor and the circuit resistor in the resistor array, the target arrangement is the preferred arrangement of the resistor array, the target resistance value is the resistance value of the circuit resistor obtained under the target mapping relationship, and the target performance parameter is the preferred performance parameter obtained based on iterative evolution.

In this embodiment, a corresponding resistor array is created based on a conversion circuit of a digital-to-analog converter, a mapping relationship between a layout resistor and a circuit resistor is established, a resistance value of the circuit resistor may be determined based on the mapping relationship, and then a performance model of the digital-to-analog converter is constructed based on the mapping relationship. Subsequently, iterative evolution is performed on the mapping relationship to obtain a target mapping relationship, and then a target arrangement of the layout resistor in the resistor array and a target resistance value of the circuit resistor are determined, to enable the performance model to output a target performance parameter, thus achieving optimization of the resistor array. The optimized resistor array is beneficial to improving the adaptability between the switch and the resistor array in the DAC, so as to further improve the conversion accuracy of the DAC, thus being beneficial to better meeting the requirements for DAC accuracy in a highly integrated system environment.

In an embodiment of the present disclosure, the method further includes: for each row of layout resistors in the resistor array, obtaining the simulated resistance value by simulation based on an existing resistance value deviation.

In some embodiments, a mapping relationship is obtained after each iterative evolution, and an arrangement of the resistor array may be obtained based on the mapping relationship, thus determining the simulated resistance value after one iterative evolution and further determining the resistance value of the circuit resistor and the output result of the performance model.

In this embodiment, since the layout resistors at different positions may be affected by process deviations to different degrees, different rows of resistors exhibit certain resistance value deviations correspondingly. Therefore, the resistance values of each row of resistors in the resistor array exhibit a certain distribution characteristic, and the resistance value of each layout resistor may be obtained by simulation based on this distribution characteristic.

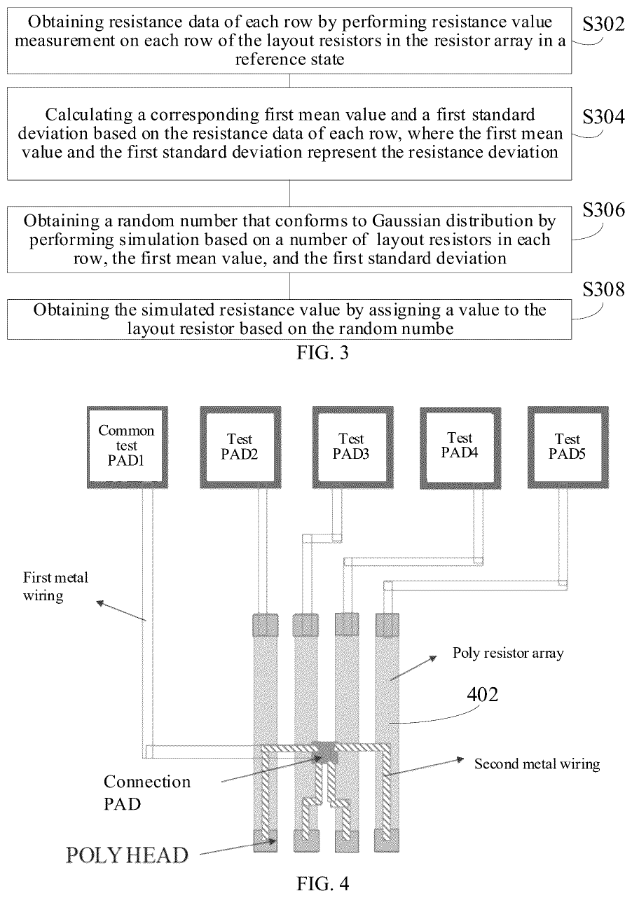

As shown in FIG. 3, in an embodiment of the present disclosure, obtaining the simulated resistance value by simulation based on the existing resistance value deviation includes followings steps.

In step S302, resistance data of each row is obtained by performing resistance value measurement on each row of layout resistors in the resistor array in a reference state.

In some embodiments, the reference state may be understood as an initial design state of the resistor array.

In some embodiments, the resistor array set to the reference state may be set in the same wafer or different wafers, and may also be set in the same integrated circuit product or different integrated circuit products, including but not limited to semiconductor devices, circuits, chips, chiplets and wafers, etc.

In step S304, a corresponding first mean value and a first standard deviation are calculated based on the resistance data of each row, where the first mean value and the first standard deviation represent the resistance value deviation.

In step S306, a random number that conforms to Gaussian distribution is obtained by performing simulation based on a number of the layout resistors in each row, the first mean value, and the first standard deviation.

In step S308, the simulated resistance value is obtained by assigning a value to the layout resistor based on the random number.

In some embodiments, taking an R-2R type polysilicon resistor array of N rows as an example, the resistance data of each row may be obtained by performing resistance test on the resistor array in the initial design state.

As shown in FIG. 4, in some embodiments, for a polysilicon resistor array of N=1, it includes a plurality of polysilicon resistors 402. For each polysilicon resistor, one end is connected to a corresponding test PAD through the first metal wiring, where the first metal wiring may be the wiring in the top metal layer; and, the other end is connected to a same connection PAD through the internal second metal wiring, where the second metal wiring may be the wiring in the Mn (n=1, 2, 3 . . . ) layer metal layer. The connection PAD is connected to a common test PAD through the first metal wiring.

As shown in Table 1, the corresponding first mean value and first standard deviation are calculated based on the resistance data of each row; and, based on the mean value mean and the standard deviation std (σ) of each row in Table 1, a plurality of random numbers that conform to the Gaussian distribution (mean, σ) are respectively obtained as the simulated resistance values of each row of resistors. That is, the simulated resistance values of M layout resistors in N rows are obtained. For example, m+1 numbers are generated for the first row Row1 and assigned to the layout resistors poly0 to polym respectively. The processing manner for the second row Row2 to the N-th row RowN is the same as that for Row1, where if the array is fully filled, M=N*(m+1); and if the array is not fully filled, M<N*(m+1).

In some embodiments, for the number of polysilicon resistors (i.e., layout resistors), as long as it satisfies the corresponding relationship with the circuit resistor. However, in some layout manners, unconnected dummy resistors may also be arranged around the polysilicon resistor array. This layout manner is conducive to improving the balance of the layout process and improving the performance of DAC.

TABLE 1

| | | | | Corresponding |
|---|---|---|---|---|
| | mean | std | Number of Poly | number of poly |
| row1 | R1 | σ1 | m + 1 | Poly0-m |
| row2 | . . . | . . . | . . . | . . . |
| . . . | . . . | . . . | . . . | . . . |
| . . . | . . . | . . . | . . . | . . . |
| rowN | . . . | . . . | . . . | Polyx-M |

In this embodiment, resistance data is obtained by performing resistance value measurement on each row of layout resistors in the resistor array in the reference state, and then the first mean value and the first standard deviation corresponding to each row are obtained by calculation to represent the resistance value deviation. Then, a random number that conforms to the Gaussian distribution is obtained by simulation according to the number of layout resistors in each row, the first mean value and the standard deviation. Finally, the simulated resistance value is obtained by assign a value to the layout resistor based on the random number. Since the influence of the electrical environment around the resistor on its resistance value is taken into account, the simulated resistance value obtained based on the resistance value deviation can be more in line with the actual situation, which provides a more accurate data basis for subsequent operations performed based on the simulated resistance value, such as determination of the resistance value of the circuit resistor, construction of the performance model, and arrangement optimization of the resistor array, etc., so that the final arrangement of the resistor array obtained by optimization is more in line with actual application requirements, thus achieving the purpose of improving the performance of the digital-to-analog converter.

In an embodiment of the present disclosure, constructing the performance model of the digital-to-analog converter based on the mapping relationship includes:

constructing the performance model of the digital-to-analog converter based on the mapping relationship and a calculation model of a differential nonlinear error, where a performance parameter of the digital-to-analog converter includes the differential nonlinear error.

In some embodiments, based on the model for calculating the DNL of the resistor array, by inputting the mapping relationship between the circuit resistor res and the layout resistor poly (such as res1=poly0), the DNL may be obtained, as shown in formula (1).

$$DNLn = \frac{{V}_{outn} - {V}_{outn - 1}}{LSB} - 1 \qquad ( 1 )$$

Among them, the digital-to-analog converter DAC includes a reference voltage module, a switch control network, a weighted network and an output amplifier. The reference voltage module outputs a reference voltage V_{REF} to the weighted network. The switch control network receives an input of N-bit binary codeword D. The weighted network and the switch control network generate a voltage proportional to the input codeword D based on the magnitude of the reference voltage V_{REF}. The output amplifier is used to amplify the generated voltage signal to a required level, that is Vₒᵤₜ, where n−1 and n represent two consecutive output codes with a digital input difference of 1, Vₒᵤₜₙ represents the corresponding analog output voltage when the output digital code is n, Vₒᵤₜₙ₋₁ represents the corresponding analog output voltage when the output digital code is n−1, and LSB represents an ideal unit voltage.

In this embodiment, by using DNL as the performance parameter of the digital-to-analog converter, the degree of deviation between the analog levels of two adjacent codewords output by the DAC and the ideal value may be measured, which may intuitively reflect its linearity and accuracy. In the iterative evolution process, the arrangement of the resistor array and the mapping relationship may be adjusted in a targeted manner according to the obtained DNL value, thus effectively reducing the DNL error, improving the linearity and conversion accuracy of the DAC, and realizing the design optimization of the DAC.

In an embodiment of the present disclosure, constructing the performance model of the digital-to-analog converter based on the mapping relationship and the calculation model of the differential nonlinear error includes:

determining a resistance value of the circuit resistor based on the mapping relationship and the simulated resistance value; and constructing the performance model by using the resistance value of the circuit resistor and a digital input code received by the digital-to-analog converter as an input parameter and using an error value calculated by the calculation model of the differential nonlinear error as an output parameter.

In this embodiment, the resistance value of the circuit resistor is determined based on the mapping relationship and the simulated resistance value, and the performance model is constructed by using the resistance value and the digital input code as the input parameter and using the differential nonlinear error calculation value as the output parameter, which can achieve mapping from the layout resistor characteristics (the simulated resistance value) at the physical level of the chip to the circuit resistor at the circuit logic level by using the mapping relationship. The resistance value of the circuit resistor and the digital input code are used as inputs, which can quantify the working conditions of the DAC under the influence of different digital signal inputs and actual resistance values of the resistors. The differential nonlinear error calculation value is used as the output, which can intuitively reflect the linearity deviation of the DAC output analog signal, so as to further perform iterative evolution based on the deviation, thus achieving the arrangement optimization of the resistor array.

In an embodiment of the present disclosure, establishing the mapping relationship between the layout resistor in the resistor array and the circuit resistor in the conversion circuit includes:

obtaining a circuit code by adding a first group of random codes to the circuit resistor.

In some embodiments, the generated first group of random codes is sequentially added to each circuit resistor in the conversion circuit. The circuit resistor corresponds to a unique circuit code, which remains unchanged.

A layout code is obtained by adding a second group of random codes to the layout resistor.

In some embodiments, the second group of random codes is sequentially added to each layout resistor in the resistor array so that each layout resistor has a corresponding layout code. Unlike the circuit code, the layout code may be updated based on the position adjustment of the layout resistor after each iterative evolution.

The mapping relationship is established based on a corresponding relationship between a single circuit resistor and at least one layout resistor, the circuit code and the layout code.

In some embodiments, the grouping information of the resistor array corresponding to FIG. 2 is shown in Table 2, including numbers D<0> to D<n>, where the numbers in Table 2 represent a group of R-2R resistors, with a total of N rows.

TABLE 2

| | | |
|---|---|---|
| 0 | 1 | . . . |
| . . . | . . . | . . . |
| . . . | . . . | . . . |
| . . . | . . . | . . . |
| . . . | . . . | Dn |

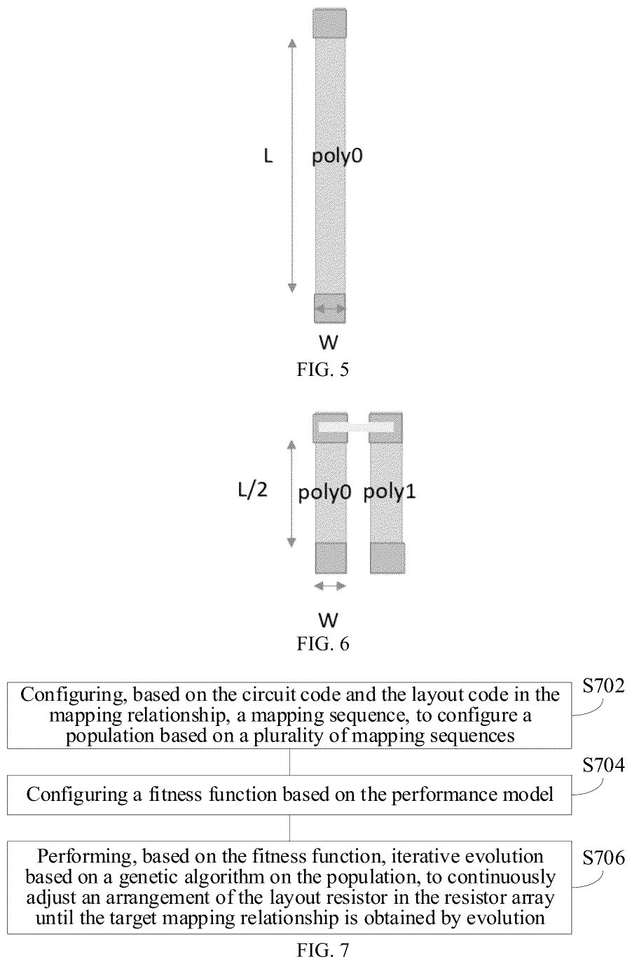

In some embodiments, the circuit resistor and the layout resistor may be in a one-to-one relationship. That is, when Poly number=1, res1=poly0. As shown in FIG. 5, the size of poly is width=W and length=L. The circuit code and the corresponding layout code are shown in Tables 3 and 4.

TABLE 3

| | | | | | | | | |
|---|---|---|---|---|---|---|---|---|
| r1 | r2 | r3 | . . . | . . . | . . . | . . . | . . . | rm + 1 |
| . . . | . . . | . . . | . . . | . . . | . . . | . . . | . . . | . . . |
| . . . | . . . | . . . | . . . | . . . | . . . | . . . | . . . | . . . |
| . . . | . . . | . . . | . . . | . . . | . . . | . . . | . . . | . . . |
| . . . | . . . | . . . | . . . | . . . | . . . | . . . | . . . | . . . |
| . . . | . . . | . . . | . . . | . . . | . . . | . . . | . . . | rM |

TABLE 4

| | | | | | | | | |
|---|---|---|---|---|---|---|---|---|
| 0 | 1 | 2 | 3 | . . . | . . . | . . . | . . . | m |
| . . . | . . . | . . . | . . . | . . . | . . . | . . . | . . . | . . . |
| . . . | . . . | . . . | . . . | . . . | . . . | . . . | . . . | . . . |
| . . . | . . . | . . . | . . . | . . . | . . . | . . . | . . . | . . . |
| . . . | . . . | . . . | . . . | . . . | . . . | . . . | . . . | M − 1 |

In some embodiments, the circuit resistor and the layout resistor may be in a one-to-two relationship, i.e., res1=poly0+poly1. That is, when Poly number=2, as shown in FIG. 6, poly0 and poly1 may be designed to have appropriate sizes so that the total resistance after series connection is consistent with the resistance value of the reference resistor. For example, the reference resistor is a single resistor when poly number=1.

In some embodiments, the sizes of poly0 and poly1 are designed to be width=W and length=L/2, and the size of the single poly is width=W and length=L/2. At this time, the circuit code is still as shown in Table 3, and the corresponding layout code is as shown in Table 5.

TABLE 5

| | | | | | | | | | | | | | | | | | |
|---|---|---|---|---|---|---|---|---|---|---|---|---|---|---|---|---|---|
| 0 | 1 | 2 | 3 | . . . | . . . | . . . | . . . | . . . | . . . | . . . | . . . | . . . | . . . | . . . | . . . | . . . | 2m − 1 |
| . . . | . . . | . . . | . . . | . . . | . . . | . . . | . . . | . . . | . . . | . . . | . . . | . . . | . . . | . . . | . . . | . . . | . . . |
| . . . | . . . | . . . | . . . | . . . | . . . | . . . | . . . | . . . | . . . | . . . | . . . | . . . | . . . | . . . | . . . | . . . | . . . |
| =. . . | . . . | . . . | . . . | . . . | . . . | . . . | . . . | . . . | . . . | . . . | . . . | . . . | . . . | . . . | . . . | . . . | . . . |
| . . . | . . . | . . . | . . . | . . . | . . . | . . . | . . . | . . . | . . . | . . . | . . . | . . . | . . . | . . . | . . . | . . . | 2M − 1 |

As shown in FIG. 7, in an embodiment of the present disclosure, performing iterative evolution on the mapping relationship based on the performance model until the target mapping relationship is obtained by evolution includes following steps.

In step S702, a mapping sequence is configured based on the circuit code and the layout code in the mapping relationship, to configure a population based on a plurality of mapping sequences.

In some embodiments, the gene code scheme is determined according to the mapping relationship between the circuit code and the layout code, and N genes are randomly generated within the value range of each variable, i.e., N groups of corresponding relationships, which form a population P={G1, G2, G3, . . . , GN}. At this time, the genetic generation number I=0.

In an embodiment of the present disclosure, configuring the mapping sequence based on the circuit code and the layout code in the mapping relationship includes: obtaining the mapping sequence by configuring an arrangement information in the mapping sequence based on the layout code and configuring a numerical value of each position based on the circuit code and the mapping relationship.

In some embodiments, the circuit resistor and the layout resistor may be in a one-to-one relationship, which may be represented by Poly number=1. The gene is a mapping sequence generated based on the mapping relationship between poly (the layout resistor) and res (the circuit resistor). For example, if the number of res is X, the sequence of [0−(X−1)] is randomly arranged. The numerical value indicates the selected circuit code, and the position in the sequence indicates the corresponding layout code. For example, [1, 2, 3, . . . ] indicates poly0 matching res1, poly1 matching res2, poly2 matching res3, and so on, to obtain the mapping information shown in Table 6.

TABLE 6

| r1 | r2 | r3 | . . . | . . . | . . . | . . . | . . . | rm + 1 |
|---|---|---|---|---|---|---|---|---|
| 0 | 1 | 2 | . . . | . . . | . . . | . . . | . . . | m |

In some embodiments, the circuit resistor and the layout resistor may be in a one-to-two relationship, which may be represented by Poly number=2. That is, a layout resistor poly may be divided into two parts, and the two parts may be encoded separately, as shown in Table 5. For example, the number of the circuit resistor res is X. Since the number of the layout resistor is 2X, the obtained mapping sequence is a sequence randomly arranged based on [0-(2X−1)]. Since the maximum res code is only (X−1), although the code length reaches (2X−1), when the fitness function is calculated, it is need to subtract X from the part of sequence number that is greater than (X−1), so that the code [0−(X−1)] may appear in pairs in the gene information, which represents the dividing of the poly, as shown in Table 7.

TABLE 7

| r1 | | r2 | | r3 | | r4 | . . . | | . . . | | . . . | | . . . | | rm + 1 | |
|---|---|---|---|---|---|---|---|---|---|---|---|---|---|---|---|---|
| 0 | 1 | 2 | 3 | 4 | 5 | 6 | . . . | . . . | . . . | . . . | . . . | . . . | . . . | . . . | 2m | 2m + 1 |

In step S704, a fitness function is configured based on the performance model.

In some embodiments, each gene in the mapping sequence corresponds to a set of mapping relationships between poly and res. A fitness function is configured based on the performance model to obtain the fitness corresponding to each mapping relationship by calculating the fitness based on the mapping relationship, thus obtaining the corresponding fitness sequence F={F1, F2, F3, . . . , FN}.

In some embodiments, in order to determine the resistance value of the circuit resistor for calculating the fitness, it is necessary to first determine the simulated resistance value. The simulated resistance value may be determined based on the above-mentioned first mean value and first standard deviation. In the mapping sequence, the numerical value indicates the selected circuit code, and the position in the sequence indicates the corresponding layout code. The mapping sequence is used as a gene code. When the position of the layout resistor in the layout is different, the electrical resistance value that is presented is also different. In other words, the resistance value of the circuit resistor is related to the position of the layout resistor poly in the layout, that is, being related to the mapping relationship between the resistor in the circuit and the resistor in the layout. Therefore, the differential nonlinear DNL between two adjacent digital codes may be calculated based on the resistance value of the resistor array obtained after matching the gene code, and a target DNL may be determined based on a plurality of obtained DNLs as the fitness.

In some embodiments, as shown in FIG. 2, taking a 12-bit DAC as an example, that is, n=12, assuming that two adjacent digital codes are 2048 and 2049, the calculation process of DNL is shown in the following equations (2) to (8).

$$DNL 2048 = \frac{out 2049 - out 2048}{LSB} - 1 \qquad ( 2 )$$

$$Out 2049 = {V}_{out 12} \qquad ( 3 )$$

$$Out 2048 = {\sum }_{1}^{11} {V}_{outi} \qquad ( 4 )$$

$${V}_{outi} = 3.3 \cdot xi \cdot {\prod }_{i + 1}^{12} yi \qquad ( 5 )$$

$$xi = \frac{R ( i - 1 ) + r ( 3 i - 2 )}{R ( i - 1 ) + r ( 3 i - 2 ) + r ( 3 i - 1 ) + r ( 3 i )} \qquad ( 6 )$$

$$yj = \frac{r ( 3 j - 1 ) + r ( 3 j )}{R ( j - 1 ) + r ( 3 j - 2 ) + r ( 3 j - 1 ) + r ( 3 j )} \qquad ( 7 )$$

$$Ri = \frac{1}{\frac{1}{R ( i - 1 ) + r ( 3 i - 2 )} + \frac{1}{+ r ( 3 i - 1 ) + r ( 3 i )}} \qquad ( 8 )$$

Among them, i=1 . . . 12, j=2 . . . 12, and r represents the circuit resistor.

In some embodiments, based on the resistance matching result corresponding to each binary bit, the distribution of the DNL of each bit is obtained. The mean value mean and the standard deviation σ of a plurality of DNLs are calculated, the DNLs within the range of |mean−3σ| and |mean±3σ| are counted, and the maximum value among them is extracted as the target D NL to determine the fitness.

In some embodiments, MAX (|mean±3G|, | mean−3σ|)+σ may also be selected as the target DNL to be determined as the fitness.

In step S706, iterative evolution based on a genetic algorithm is performed on the population based on the fitness function to continuously adjust the arrangement of the layout resistor in the resistor array until the target mapping relationship is obtained by evolution.

In some embodiments, after completing a round of iterative evolution, the N genes are sorted from large to small according to fitness, the top s % of the genes are selected, and the remaining genes are discarded.

In some embodiments, gene selection may also adopt roulette strategy, tournament strategy, elite retention strategy, or the like.

In some embodiments, iterative evolution is completed when it is detected that the genetic generation number has reached a maximum value.

In this embodiment, a population is constructed by configuring a mapping sequence based on circuit code and layout code, and then a fitness function is configured according to a performance model. Finally, a genetic algorithm is used to perform iterative evolution on the population to obtain a target mapping relationship for generating a target resistor array. The population includes a plurality sets of potential mapping relationships for the resistor array. The fitness is determined based on the performance model. The DAC performance corresponding to each mapping sequence may be accurately evaluated to guide the evolutionary direction. The iterative evolution based on the genetic algorithm simulates the natural selection process, better mapping relationships are continuously screened out, and the arrangement of layout resistors in the array are continuously adjusted. Finally, the target mapping relationship is obtained by evolution to achieve optimization of the adaptability of the resistor array and the circuit.

In an embodiment of the present disclosure, performing, based on the fitness function, iterative evolution based on the genetic algorithm on the population until the target mapping relationship is obtained by evolution, includes: for a single gene code, determining a resistance value of the circuit resistor based on the mapping sequence and the configured simulated resistance value; inputting the resistance value of the circuit resistor and the configured digital input code into the performance model, to enable the performance model to correspondingly output a plurality of performance parameters as a plurality of candidate parameters; calculating a second mean value and a second standard deviation based on the plurality of candidate parameters; determining a screening range based on the second mean value and the second standard deviation; determining a candidate parameter with a maximum value in the screening range as fitness of the single gene code; for a plurality of fitness of each generation of the population, performing sorting on the plurality of fitness to screen out a genetic genome based on a sorting result and obtain a next generation of the population by performing iterative evolution on the genetic genome; in response to detecting that the iterative evolution satisfies a termination condition, obtaining a final generation of genome; and, determining the target arrangement based on the target mapping relationship by selecting a target gene from the final generation of genome, where the target gene corresponds to the target mapping relationship.

In some embodiments, a gene corresponds to an arrangement of the resistor array. After collecting the plurality of performance parameters correspondingly output by the performance model, a second mean value and a second standard deviation of these performance parameters are counted. The second mean value reflects the average level of this group of performance parameters, and the second standard deviation reflects the degree of dispersion of these performance parameters relative to the mean value, where each performance parameter corresponds to the DNL of each digital code bit in the conversion circuit.

In some embodiments, after obtaining the plurality of performance parameters, that is, obtaining the distribution of DNL of each bit, the second mean value mean and the second standard deviation σ are calculated, the |mean±3σ| of DNL of each bit is counted, and the maximum value is extracted as the fitness. In addition, the fitness may also be determined based on MAX mean±3σ|+σ.

In this embodiment, in each iteration, a single gene code corresponds to a resistor array, the resistance value of the circuit resistor is determined according to the mapping sequence and the simulated resistance value, and a plurality of candidate parameters are obtained through the performance model in combination with the digital input code. The fitness of the single gene code is obtained by performing calculation and processing on these parameters, and the performance of the DAC under the resistor array is evaluated by using the screened fitness value, which may ensure the reliability of the evaluation. The genetic genome is screened out by sorting the fitness of each generation of the population. It is continuously iterated and evolved to make the population develop in the direction of better performance. When the termination condition is satisfied and the final generation of the genome is obtained, the target gene and the corresponding target mapping relationship are selected therefrom, and then the preferred arrangement of the resistor array is determined to optimize the layout of the resistor array of the DAC and thus improve its performance.

In an embodiment of the present disclosure, obtaining the next generation of the population by performing iterative evolution on the genetic genome includes: obtaining the next generation of the population by performing hybridization operation and mutation operation on the genetic genome.

In some embodiments, before configuring the population, the parameters that need to be defined include: the number N of individuals in the population, the crossover probability s %, the mutation probability m %, the maximum genetic generation number Imax.

In some embodiments, the process of the hybridization operation includes: using an ordered hybridization method, randomly selecting two genes according to s %, randomly selecting two mutation points on the genes, exchanging the genes between the mutation points, causing the genes outside the mutation points to be determined, sequentially traversing the gene sequence behind the mutation points of the parent, skipping the gene sequence that already exists in the offspring, and forming the gene after hybridization by filling in sequence.

In some embodiments, the process of the mutation operation includes selecting the genes according to m %. The actual operation is similar to the crossover operation, and the focus is on generating non-repetitive sequences.

In some embodiments, the next generation of the population P′={G′1, G′2, G′3, . . . , G′N} is generated through the crossover operation and the mutation operation.

In this embodiment, the next generation of the population is obtained by performing hybridization operation and mutation operation on the genetic genome. On the one hand, the hybridization operation may be used to combine different excellent genes to increase the genetic diversity of the population, provide more possibilities for evolution, and promote continuous optimization of the performance of the digital-to-analog converter. On the other hand, the mutation operation may be used to introduce new genetic features to prevent from falling into local optimality, help quickly find better target mapping relationships and layout resistor arrangements, and improve the overall performance of the digital-to-analog converter.

In an embodiment of the present disclosure, selecting the target gene from the final generation of genome includes: calculating a plurality of fitness corresponding to the final generation of genome based on the performance model; and determining a gene code with the maximum fitness in the final generation of genome as the target gene.

In some embodiments, fitness calculation, detection of whether the termination condition is satisfied, genetic selection, genetic crossover and genetic mutation are repeated, to generate a new population by evolution, until the termination condition is satisfied. At this time, the gene with the maximum fitness is the current optimal arrangement scheme of the resistor array, and the optimization process ends.

In some embodiments, an iterative evolution based on a genetic algorithm is performed on the intermediate population until it is detected that the iterative evolution satisfies a termination condition, thus obtaining a final generation of the population.

In some embodiments, the termination condition includes, but is not limited to, the above-mentioned detection of reaching the maximum genetic generation number Imax, detection of the fitness value reaching a threshold, detection of the fitness value change being less than a threshold, and detection of reaching the maximum running time, etc.

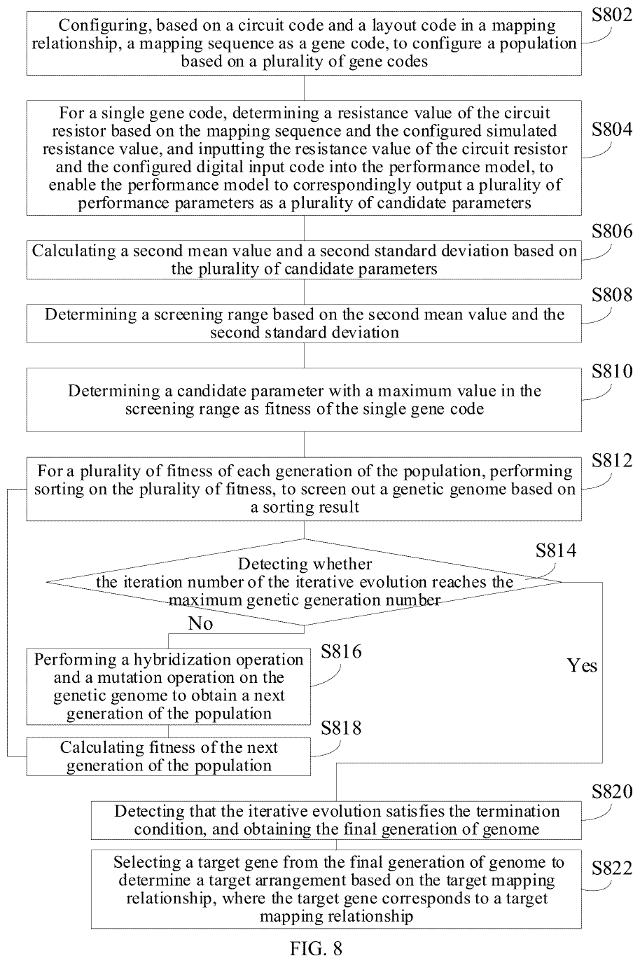

A shown in FIG. 8, a method for optimizing arrangement of a resistor array according to another embodiment of the present disclosure includes following steps.

In step S802, a mapping sequence is configured, based on a circuit code and a layout code in a mapping relationship, as a gene code to configure a population based on a plurality of gene codes.

In step S804, for a single gene code, a resistance value of the circuit resistor is determined based on the mapping sequence and the configured simulated resistance value, and the resistance value of the circuit resistor and the configured digital input code are input into the performance model to enable the performance model to correspondingly output a plurality of performance parameters as a plurality of candidate parameters.

In step S806, a second mean value and a second standard deviation are calculated based on the plurality of candidate parameters.

In step S808, a screening range is determined based on the second mean value and the second standard deviation.

In step S810, a candidate parameter with the maximum value in the screening range is determined as the fitness of the single gene code.

In step S812, for a plurality of fitness of each generation of the population, sorting is performed on the plurality of fitness to screen out a genetic genome based on the sorting result.

In step S814, it is detected whether the iteration number of the iterative evolution reaches the maximum genetic generation number; if “yes”, it is proceeded to step S820; and if “no”, it is proceeded to step S816.

In step S816, a hybridization operation and a mutation operation are performed on the genetic genome to obtain a next generation of the population.

In step S818, the fitness of the next generation of the population is calculated, and it is returned to step S812.

In step S820, it is detected that the iterative evolution satisfies the termination condition, and the final generation of genome is obtained.

In step S822, a target gene is selected from the final generation of genome to determine a target arrangement based on the target mapping relationship, where the target gene corresponds to a target mapping relationship.

In this embodiment, the arrangement of the resistor array is optimized based on a genetic algorithm, so that the optimal arrangement scheme of resistors in the layout may be obtained quickly and efficiently, thus realizing the prediction of DAC DNL performance, which is beneficial to improving efficiency and reducing costs.

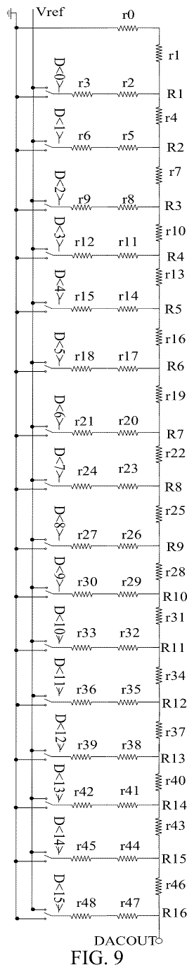

In an embodiment of the present disclosure, as shown in FIG. 9, assuming that the conversion circuit is of a 16-bit R-2R structure, the corresponding number of rows in the resistor array is 6.

The first mean value and the first standard deviation (mean, σ) of each row may be obtained through testing, as shown in Table 8.

TABLE 8

| | | | Number of layout | Corresponding number |
|---|---|---|---|---|
| | mean | std | resistor | of Poly |
| Row1 | R1 | σ1 | 9 | Poly0-8 |
| Row2 | R2 | σ2 | 9 | Poly9-17 |
| Row3 | R3 | σ3 | 9 | Poly18-26 |
| Row4 | R4 | σ4 | 9 | Poly27-35 |
| Row5 | R5 | σ5 | 9 | Poly36-44 |
| Row6 | R6 | σ6 | 4 | Poly45-48 |

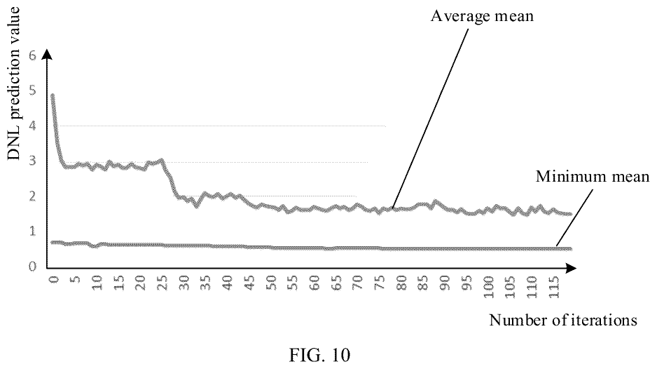

For this R-2R array, after optimization by using the genetic algorithm (800 populations, 300 generations), the best arrangement may be obtained and it satisfies the requirement of the DNL prediction value<3. FIG. 10 shows the relationship curve between the DNL prediction value and the number of iterations.

Based on the optimal individual output by the genetic algorithm, the corresponding relationship of res-poly may be obtained. If poly number=1, as shown in Table 9 to Table 11, Table 9 is used to illustrate the grouping information of the resistor array of the 16-bit conversion circuit, which includes 6 rows, Table 10 shows the corresponding circuit resistor code, and Table 11 shows the corresponding layout resistor code.

In some embodiments, the <F> bit corresponding to r0 may be placed in a non-first bit.

In some embodiments, as shown in Table 9, the <F> bit is placed at the end. At this time, D<0> at the first bit corresponds to r1~r3. Therefore, r1 corresponds to POLY at the first bit. When the circuit resistor and the layout resistor are in a one-to-one relationship, that is, poly number=1, r1=poly0, as shown in Table 9 to Table 11, where Table 9 is used to illustrate the grouping information of the resistor array of the 16-bit conversion circuit, which includes 6 row, Table 10 shows the corresponding circuit resistor code, and Table 11 shows the corresponding layout resistor code.

In some embodiments, as shown in Table 10 and Table 12, when the circuit resistor and the layout resistor are in a one-to-two relationship, r1=poly0+poly1.

TABLE 9

| | | |
|---|---|---|
| 0 | 1 | 2 |
| 3 | 4 | 5 |
| 6 | 7 | 8 |
| 9 | 10 | 11 |
| 12 | 13 | 14 |
| 15 | F | |

TABLE 10

| | | | | | | | | |
|---|---|---|---|---|---|---|---|---|
| r1 | r2 | r3 | r4 | r5 | r6 | r7 | r8 | r9 |
| r10 | r11 | r 12 | r 13 | r 14 | r 15 | r 16 | r 17 | r 18 |
| r 19 | r 20 | r 21 | r 22 | r 23 | r 24 | r 25 | r 26 | r 27 |
| r 28 | r 29 | r 30 | r 31 | r 32 | r 33 | r 34 | r 35 | r 36 |
| r 37 | r 38 | r 39 | r 40 | r 41 | r 42 | r 43 | r 44 | r 45 |
| r46 | r 47 | r 48 | r 0 | | | | | |

TABLE 11

| | | | | | | | | |
|---|---|---|---|---|---|---|---|---|
| 0 | 1 | 2 | 3 | 4 | 5 | 6 | 7 | 8 |
| 9 | 10 | 11 | 12 | 13 | 14 | 15 | 16 | 17 |
| 18 | 19 | 20 | 21 | 22 | 23 | 24 | 25 | 26 |
| 27 | 28 | 29 | 30 | 31 | 32 | 33 | 34 | 35 |
| 36 | 37 | 38 | 39 | 40 | 41 | 42 | 43 | 44 |
| 45 | 46 | 47 | 48 | | | | | |

In an embodiment of the present disclosure, if poly number=2, combined with Table 10 and Table 12, the mapping relationship between res and poly may be written as: res1=poly0+poly1, . . . , res0=poly96+poly97, and the obtained array structure is shown in Table 12.

TABLE 12

| | | | | | | | | | | | | | | | | | |
|---|---|---|---|---|---|---|---|---|---|---|---|---|---|---|---|---|---|
| 0 | 1 | 2 | 3 | 4 | 5 | 6 | 7 | 8 | 9 | 10 | 11 | 12 | 13 | 14 | 15 | 16 | 17 |
| 18 | 19 | 20 | 21 | 22 | 23 | 24 | 25 | 26 | 27 | 28 | 29 | 30 | 31 | 32 | 33 | 34 | 35 |
| 36 | 37 | 38 | 39 | 40 | 41 | 42 | 43 | 44 | 45 | 46 | 47 | 48 | 49 | 50 | 51 | 52 | 53 |
| 54 | 55 | 56 | 57 | 58 | 59 | 60 | 61 | 62 | 63 | 64 | 65 | 66 | 67 | 68 | 69 | 70 | 71 |
| 72 | 73 | 74 | 75 | 76 | 77 | 78 | 79 | 80 | 81 | 82 | 83 | 84 | 85 | 86 | 87 | 88 | 89 |
| 90 | 91 | 92 | 93 | 94 | 95 | 96 | 97 | | | | | | | | | | |

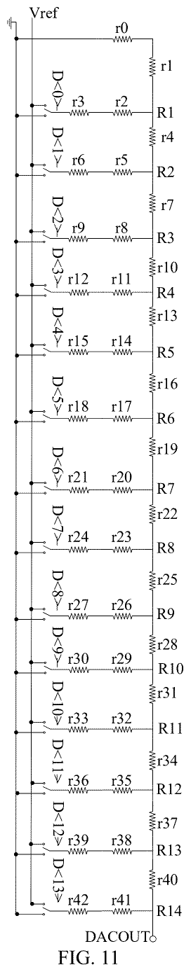

As shown in FIG. 11, for a 14-bit R-2R resistor array, based on the mean value and σ of a row, random numbers that conform to the Gaussian distribution (mean, σ) are generated for each row as the simulated resistance values, i.e., poly values (43 in total). Table 13-1 and Table 13-2 show the mapping relationship among the grouping information of the resistor array in the reference state, the layout resistor poly, and the circuit resistor res.

In some embodiments, as shown in Table 13-1, the <F> bit corresponding to r0 may be placed at the first bit. Combining Table 13-1 and Table 13-2, the <F> at the first bit corresponds to r0, and r0 corresponds to the POLY at the first bit, that is, r0=poly0.

In some embodiments, when the circuit resistor and the layout resistor are in a one-to-two relationship, i.e., r0=poly0+poly1 (not shown in the table), a corresponding relationship of res-poly may also be obtained.

Those skilled in the art can appreciate that, although Table 13-1 and Table 13-2 are two tables, the resistor arrays corresponding Table 13-1 and Table 13-2 may be arranged in the same row or different rows according to actual conditions. That is, Table 13-1 and Table 13-2 may represent a 14-bit R-2R resistor array of a single row or a 14-bit R-2R resistor array of a plurality of rows.

In some embodiments, an implementation method for obtaining the resistance data of each row by measuring the resistance value of each row of layout resistors in the resistor array in the reference state, calculating the corresponding first mean value and first standard deviation based on the resistance data of each row, and respectively obtaining a plurality of random numbers conforming to the Gaussian distribution (mean, σ), based on the mean value mean and the standard deviation std (o) of each row, as the simulated resistance value of each row of resistors, includes the following.

If poly0 to poly43 are arranged in the same row, values are assigned to poly0 to poly43 based on the resistance value test result of the same row of the resistor array in the reference state.

Another implementation method for obtaining the simulated resistance value includes the following: poly0 to poly21 are arranged in the first row, poly22 to poly 43 are arranged in the second row, values are assigned to poly0 to poly21 based on the resistance value test result of the first row of the resistor array in the reference state, and values are assigned to poly22 to poly43 based on the resistance value test result of the second row of the resistor array in the reference state.

TABLE 13-1

| F | 0 | | | 1 | | | 2 | | | 3 | | | 4 | | | 5 | | | 6 | | |
|---|---|---|---|---|---|---|---|---|---|---|---|---|---|---|---|---|---|---|---|---|---|
| 0 | 1 | 2 | 3 | 4 | 5 | 6 | 7 | 8 | 9 | 10 | 11 | 12 | 13 | 14 | 15 | 16 | 17 | 18 | 19 | 20 | 21 |
| r0 | r1 | r2 | r3 | r4 | r5 | r6 | r7 | r8 | r9 | r10 | r11 | r12 | r13 | r14 | r15 | r16 | r17 | r18 | r19 | r20 | r21 |

TABLE 13-2

| 7 | | | 8 | | | 9 | | | 10 | | | 11 | | | 12 | | | 13 | | |
|---|---|---|---|---|---|---|---|---|---|---|---|---|---|---|---|---|---|---|---|---|
| 22 | 23 | 24 | 25 | 26 | 27 | 28 | 29 | 30 | 31 | 32 | 33 | 34 | 35 | 36 | 37 | 38 | 39 | 40 | 41 | 42 |
| r22 | r23 | r24 | r25 | r26 | r27 | r28 | r29 | r30 | r31 | r32 | r33 | r34 | r35 | r36 | r37 | r38 | r39 | r40 | r41 | r43 |

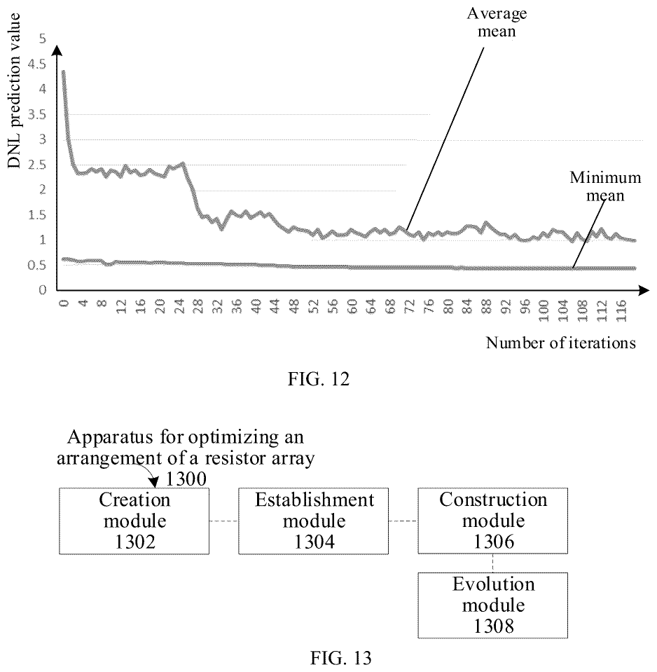

After iterative evolution of the genetic algorithm, the optimal arrangement may be obtained, and it satisfies the requirement of the DNL prediction value<3. FIG. 12 shows the relationship curve between the DNL prediction value and the number of iterations.

Accordingly, after iterative evolution of the genetic algorithm, the optimal grouping information of the resistor array in the R-2R array structure is obtained, and the illustration of the position of res in the circuit and the position of poly in the layout are shown in Table 14-1 and Table 14-2.

It can be understood by those skilled in the art that, although Table 14-1 and Table 14-2 are two tables, the resistor arrays corresponding to Table 14-1 and Table 14-2 may be arranged in the same row or different rows according to actual conditions, so as to correspond to Table 13-1 and Table 13-2.

TABLE 14-1

| F | 0 | | | 1 | | | 7 | | | 8 | | | 9 | | | 5 | | | 6 | | |
|---|---|---|---|---|---|---|---|---|---|---|---|---|---|---|---|---|---|---|---|---|---|
| 0 | 1 | 2 | 3 | 4 | 5 | 6 | 22 | 23 | 24 | 25 | 26 | 27 | 28 | 29 | 30 | 16 | 17 | 18 | 19 | 20 | 21 |
| r0 | r1 | r2 | r3 | r4 | r5 | r6 | r22 | r23 | r24 | r25 | r26 | r27 | r28 | r29 | r30 | r16 | r17 | r18 | r19 | r20 | r21 |

TABLE 14-2

| 2 | | | 3 | | | 4 | | | 10 | | | 11 | | | 12 | | | 13 | | |
|---|---|---|---|---|---|---|---|---|---|---|---|---|---|---|---|---|---|---|---|---|
| 7 | 8 | 9 | 10 | 11 | 12 | 13 | 14 | 15 | 31 | 32 | 33 | 34 | 35 | 36 | 37 | 38 | 39 | 40 | 41 | 42 |
| r7 | r8 | r9 | r10 | r11 | r12 | r13 | r14 | r15 | r31 | r32 | r33 | r34 | r35 | r36 | r37 | r38 | r39 | r40 | r41 | r43 |

In this embodiment, given the conversion circuit and the required N-row arrangement, the target arrangement of the resistor array, i.e., the arrangement of the array in the layout with the best DNL performance, may be obtained by optimization using a genetic algorithm, so as to guide related design and optimization.

Those skilled in the art may appreciate that, the optimization scheme for the arrangement of the resistor array in the present disclosure is not only applicable to DAC resistor arrays, but also to other types of resistor arrays, and the modeling of the resistor array includes but is not limited to the process conditions, the number of rows, the size, and the number of the resistors.

It should be noted that the above drawings are only schematic illustrations of the processes included in the method according to an example embodiment of the present disclosure, and are not intended to be limiting. It is easy to understand that the processes shown in the above drawings do not indicate or limit the time sequence of these processes. In addition, it is also easy to understand that these processes may be performed synchronously or asynchronously, for example, in a plurality of modules.

It can be appreciated by those skilled in the art that various aspects of the present disclosure may be implemented as a system, method or program product. Therefore, various aspects of the present disclosure may be specifically implemented in the following forms, i.e.: a complete hardware implementation, a complete software implementation (including firmware, microcode, etc.), or an implementation combining the aspects of hardware and software, which may be collectively referred to herein as a “circuit”, “module” or “system”.

An apparatus 1300 for optimizing an arrangement of a resistor array according to an embodiment of the present disclosure is described below with reference to FIG. 13. The apparatus 1300 for optimizing an arrangement of a resistor array shown in FIG. 13 is only an example and should not limit the function and use scope of the embodiments of the present disclosure.

The apparatus 1300 for optimizing an arrangement of a resistor array is presented in the form of a hardware module. The components of the apparatus 1300 for optimizing an arrangement of a resistor array may include but are not limited to: a creation module 1302, configured to create a corresponding resistor array based on a conversion circuit of a digital-to-analog converter; an establishment module 1304, configured to establish a mapping relationship between a layout resistor in the resistor array and a circuit resistor in the conversion circuit, where the layout resistor has a simulated resistance value, and the mapping relationship is used to determine a resistance value of the circuit resistor based on the layout resistor and the corresponding simulated resistance value; a construction module 1306, configured to construct a performance model of the digital-to-analog converter based on the mapping relationship; and an evolution module 1308, configured to perform iterative evolution on the mapping relationship based on the performance model until a target mapping relationship is obtained by evolution, where the target mapping relationship is suitable for determining a target arrangement of the layout resistor in the resistor array, to determine a target resistance value of the circuit resistor based on the target arrangement, and enable the performance model to output a target performance parameter based on the target resistance value.

It can be appreciated by those skilled in the art that various aspects of the present disclosure may be implemented as a system, method or program product. Therefore, various aspects of the present disclosure may be specifically implemented in the following forms, i.e.: a complete hardware implementation, a complete software implementation (including firmware, microcode, etc.), or an implementation combining the aspects of hardware and software, which may be collectively referred to herein as a “circuit”, “module” or “system”.

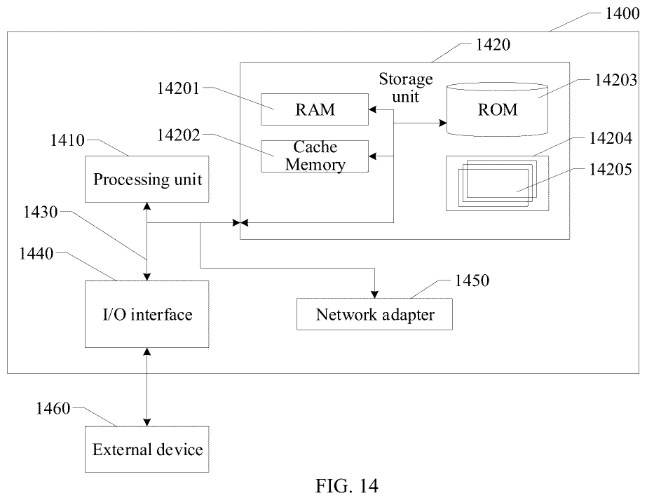

The electronic device 1400 according to this embodiment of the present disclosure is described below with reference to FIG. 14. The electronic device 1400 shown in FIG. 14 is only an example and should not bring any limitation to the functions and use scope of the embodiments of the present disclosure.

As shown in FIG. 14, the electronic device 1400 is presented in the form of a general computing device. The components of the electronic device 1400 may include but are not limited to: at least one processing unit 1410, at least one storage unit 1420, and a bus 1430 connecting different system components (including the storage unit 1420 and the processing unit 1410).

Among them, the storage unit stores a program code, and the program code can be executed by the processing unit 1410, so that the processing unit 1410 performs the steps according to various example embodiments of the present disclosure described in the above “example method” part of the present specification. For example, the processing unit 1410 can perform the scheme described in steps S102 to S108 as shown in FIG. 1.

The storage unit 1420 may include a readable medium in the form of a volatile storage unit, such as a random access storage unit (RAM) 14201 and/or a cache memory unit 14202, and may further include a read-only storage unit (ROM) 14203.

The storage unit 1420 may also include a program/utility 14204 having a set (at least one) of program modules 14205, such program module 14205 including but not limited to: an operating system, one or more applications, other program modules, and program data. Each of these examples or a certain combination of these examples may include an implementation of a network environment.

The bus 1430 may represent one or more of several types of bus structures, including a memory unit bus or memory unit controller, a peripheral bus, an accelerated graphics port, a processing unit, or a local bus using any of a variety of bus structures.

The electronic device 1400 may also communicate with one or more external devices 1460 (e.g., keyboards, pointing devices, Bluetooth devices, etc.), may also communicate with one or more devices that enable a user to interact with the electronic device 1400, and/or may communicate with any device (e.g., routers, modems, etc.) that enables the electronic device 1400 to communicate with one or more other computing devices. Such communication may be performed through an input/output (I/O) interface 1440. In addition, the electronic device 1400 may also communicate with one or more networks (e.g., local area networks (LANs), wide area networks (WANs), and/or public networks, such as the Internet) through a network adapter 1450. As shown in the drawing, the network adapter 1460 communicates with other modules of the electronic device 1400 through the bus 1430. It should be understood that, although not shown in the drawing, other hardware and/or software modules may be used in conjunction with the electronic device 1400, including but not limited to: microcode, device drivers, redundant processing units, external disk drive arrays, RAID systems, tape drives, and data backup storage systems, etc.

Through the description of the above implementation, it is easy for those skilled in the art to understand that the example implementation described here can be implemented by software, or by software combined with necessary hardware. Therefore, the technical solution according to the implementation of the present disclosure can be embodied in the form of a software product. The software product can be stored in a non-volatile storage medium (which can be a CD-ROM, a USB flash drive, a mobile hard disk, etc.) or on a network, and includes several instructions to enable a computing device (which can be a personal computer, a server, a terminal device, or a network device, etc.) to perform the method according to the implementation of the present disclosure.

In an example embodiment of the present disclosure, there is further provided a non-transitory computer-readable storage medium, on which a program product capable of implementing the above method of the present specification is stored. In some possible implementations, various aspects of the present disclosure may also be implemented in the form of a program product, which includes a program code, and when the program product is run on an electronic device, the program code is used to enable the electronic device to perform the steps according to various example implementations of the present disclosure described in the above “example method” part of the present specification.

According to another aspect of the present disclosure, there is provided a computer program product, and a computer program is stored on the computer program product. When the computer program is executed by a processor, the method for optimizing the arrangement of the resistor array is implemented.

The program product for implementing the above method according to an embodiment of the present disclosure may adopt a portable compact disk read-only memory (CD-ROM) and include program code, and may be run on an electronic device, such as a personal computer. However, the program product of the present disclosure is not limited to this. In this document, the readable storage medium may be any tangible medium containing or storing a program, and the program may be used by or in combination with an instruction execution system, apparatus, or device.

The program product may be any combination of one or more readable media. The readable medium may be a readable signal medium or a readable storage medium. The readable storage medium may be, for example, but not limited to, an electrical, magnetic, optical, electromagnetic, infrared, or semiconductor system, apparatus or device, or any combination of them. More specific examples (non-exhaustive list) of the readable storage medium include: an electrical connection with one or more wires, a portable disk, a hard disk, a random access memory (RAM), a read-only memory (ROM), an erasable programmable read-only memory (EPROM or flash memory), an optical fiber, a portable compact disk read-only memory (CD-ROM), an optical storage device, a magnetic storage device, or any suitable combination of them.

The computer readable signal medium may include data signals propagated in baseband or as part of a carrier wave, in which readable program code is carried. Such propagated data signals may take a variety of forms, including but not limited to electromagnetic signals, optical signals, or any suitable combination of the above. The readable signal medium may also be any readable medium other than a readable storage medium. The readable medium may send, propagate, or transmit a program for use by or in conjunction with an instruction execution system, apparatus, or device.

The program code contained on the readable medium may be transmitted by using any appropriate medium, including but not limited to wireless, wired, optical cable, RF, or any suitable combination of the foregoing, etc.

Program code for performing the operations of the present disclosure may be written in any combination of one or more programming languages, including object-oriented programming languages such as Java, C++, etc., and conventional procedural programming languages such as “C” or similar programming languages. The program code may be executed entirely on the user computing device, partially on the user device, as a separate software package, partially on the user computing device and partially on a remote computing device, or entirely on a remote computing device or server. In the case of involving a remote computing device, the remote computing device may be connected to the user computing device through any type of network, including a local area network (LAN) or a wide area network (WAN), or may be connected to an external computing device (e.g., via the Internet by using an Internet service provider).

It should be noted that, although several modules or units of the device for action execution are mentioned in the above detailed description, this division is not mandatory. In fact, according to the embodiments of the present disclosure, the features and functions of two or more modules or units described above can be embodied in one module or unit. On the contrary, the features and functions of one module or unit described above can be further divided into a plurality of modules or units to be embodied.

In addition, although the steps of the method in the present disclosure are described in a specific order in the drawings, this does not require or imply that the steps must be performed according to this specific order, or that all the steps shown must be performed to achieve the desired results. Additionally or alternatively, some steps may be omitted, a plurality of steps may be combined into one step, and/or one step may be decomposed into a plurality of steps, etc.

Through the description of the above implementation, it is easy for those skilled in the art to understand that the example implementation described here can be implemented by software, or by combining software with necessary hardware. Therefore, the technical solution according to the implementation of the present disclosure can be embodied in the form of a software product. The software product can be stored in a non-volatile storage medium (which can be a CD-ROM, a USB flash drive, a mobile hard disk, etc.) or on a network, and includes several instructions to enable a computing device (which can be a personal computer, a server, a mobile terminal, or a network device, etc.) to perform the method according to the implementation of the present disclosure.

Those skilled in the art may easily think of other embodiments of the present disclosure after considering the specification and practicing the present disclosure herein. The present application is intended to cover any modification, use or adaptation of the present disclosure, which follows the general principles of the present disclosure and includes common general knowledge or conventional technical means in the art that are not disclosed in the present disclosure. The specification and examples are intended to be exemplary only, and the true scope and spirit of the present disclosure are indicated by the appended claims.

What is claimed is:

1. A method for optimizing an arrangement of a resistor array, comprising:
creating a corresponding resistor array based on a conversion circuit of a digital-to-analog converter;
establishing a mapping relationship between a layout resistor in the resistor array and a circuit resistor in the conversion circuit, wherein the layout resistor has a simulated resistance value, and the mapping relationship is used to determine a resistance value of the circuit resistor based on the layout resistor and the corresponding simulated resistance value;
constructing a performance model of the digital-to-analog converter based on the mapping relationship; and
performing iterative evolution on the mapping relationship based on the performance model until a target mapping relationship is obtained by evolution, wherein the target mapping relationship is used to determine a target arrangement of the layout resistor in the resistor array, to determine a target resistance value of the circuit resistor based on the target arrangement, and enable the performance model to output a target performance parameter based on the target resistance value.

2. The method according to claim 1, further comprising:
for each row of layout resistors in the resistor array, obtaining the simulated resistance value by simulation based on an existing resistance value deviation.

3. The method according to claim 2, wherein obtaining the simulated resistance value by simulation based on the existing resistance value deviation comprises:
obtaining resistance data of each row by performing resistance value measurement on each row of layout resistors in the resistor array in a reference state;
calculating a corresponding first mean value and a first standard deviation based on the resistance data of each row, wherein the first mean value and the first standard deviation represent the resistance value deviation;
obtaining a random number that conforms to Gaussian distribution by performing simulation based on a number of layout resistors in each row, the first mean value, and the first standard deviation; and
obtaining the simulated resistance value by assigning a value to the layout resistor based on the random number.

4. The method according to claim 1, wherein constructing the performance model of the digital-to-analog converter based on the mapping relationship comprises:
constructing the performance model of the digital-to-analog converter based on the mapping relationship and a calculation model of a differential nonlinear error, wherein a performance parameter of the digital-to-analog converter comprises the differential nonlinear error.

5. The method according to claim 4, wherein, constructing the performance model of the digital-to-analog converter based on the mapping relationship and the calculation model of the differential nonlinear error, comprises:
determining a resistance value of the circuit resistor based on the mapping relationship and the simulated resistance value; and
constructing the performance model by using the resistance value of the circuit resistor and a digital input code received by the digital-to-analog converter as input parameters and using an error value calculated by the calculation model of the differential nonlinear error as an output parameter.

6. The method according to claim 1, wherein establishing the mapping relationship between the layout resistor in the resistor array and the circuit resistor in the conversion circuit comprises:
obtaining a circuit code by adding a first group of random codes to the circuit resistor;
obtaining a layout code by adding a second group of random codes to the layout resistor; and
establishing the mapping relationship based on a corresponding relationship between a single circuit resistor and at least one layout resistor, the circuit code and the layout code.

7. The method according to claim 6, wherein performing iterative evolution on the mapping relationship based on the performance model until the target mapping relationship is obtained by evolution, comprises:
configuring, based on the circuit code and the layout code in the mapping relationship, a mapping sequence as a gene code, to configure a population based on a plurality of gene codes;
configuring a fitness function based on the performance model; and
performing, based on the fitness function, iterative evolution based on a genetic algorithm on the population, to continuously adjust an arrangement of the layout resistor in the resistor array until the target mapping relationship is obtained by evolution.

8. The method according to claim 7, wherein configuring the mapping sequence based on the circuit code and the layout code in the mapping relationship comprises:
obtaining the mapping sequence by configuring an arrangement information in the mapping sequence based on the layout code and configuring a numerical value of each position based on the circuit code and the mapping relationship.

9. The method according to claim 7, wherein performing, based on the fitness function, iterative evolution based on the genetic algorithm on the population until the target mapping relationship is obtained by evolution, comprises:
for a single gene code, determining a resistance value of the circuit resistor based on the mapping sequence and the configured simulated resistance value;
inputting the resistance value of the circuit resistor and the configured digital input code into the performance model, to enable the performance model to correspondingly output a plurality of performance parameters as a plurality of candidate parameters;
calculating a second mean value and a second standard deviation based on the plurality of candidate parameters;
determining a screening range based on the second mean value and the second standard deviation;
determining a candidate parameter with a maximum value in the screening range as fitness of the single gene code;
for a plurality of fitness of each generation of the population, performing sorting on the plurality of fitness, to screen out a genetic genome based on a sorting result and obtain a next generation of the population by performing iterative evolution on the genetic genome;
in response to detecting that the iterative evolution satisfies a termination condition, obtaining a final generation of genome; and
determining the target arrangement based on the target mapping relationship by selecting a target gene from the final generation of genome, wherein the target gene corresponds to the target mapping relationship.

10. The method according to claim 9, wherein obtaining the next generation of the population by performing iterative evolution on the genetic genome comprises:
obtaining the next generation of the population by performing a hybridization operation and a mutation operation on the genetic genome.

11. The method according to claim 9, wherein selecting the target gene from the final generation of genome comprises:
calculating a plurality of fitness corresponding to the final generation of genome based on the performance model; and
determining a gene code with maximum fitness in the final generation of genome as the target gene.

12. The method according to claim 1, wherein creating the corresponding resistor array based on the conversion circuit of the digital-to-analog converter comprises:
creating the resistor array based on a number of resistors in the conversion circuit, a configured number of rows in the resistor array, a resistor process and a resistor size.

13. The method according to claim 1, wherein:
the layout resistor comprises at least one of a polysilicon resistor, a metal resistor or a thin film resistor.

14. An electronic device, comprising:
a processor; and
a memory, configured to store an executable instruction by the processor;
wherein the processor is configured to perform a method for optimizing an arrangement of a resistor array, and the method comprises:
creating a corresponding resistor array based on a conversion circuit of a digital-to-analog converter;
establishing a mapping relationship between a layout resistor in the resistor array and a circuit resistor in the conversion circuit, wherein the layout resistor has a simulated resistance value, and the mapping relationship is used to determine a resistance value of the circuit resistor based on the layout resistor and the corresponding simulated resistance value;
constructing a performance model of the digital-to-analog converter based on the mapping relationship; and
performing iterative evolution on the mapping relationship based on the performance model until a target mapping relationship is obtained by evolution, wherein the target mapping relationship is used to determine a target arrangement of the layout resistor in the resistor array, to determine a target resistance value of the circuit resistor based on the target arrangement, and enable the performance model to output a target performance parameter based on the target resistance value.

15. The electronic device according to claim 14, wherein the method further comprises:
for each row of layout resistors in the resistor array, obtaining the simulated resistance value by simulation based on an existing resistance value deviation.

16. The electronic device according to claim 15, wherein obtaining the simulated resistance value by simulation based on the existing resistance value deviation comprises:
obtaining resistance data of each row by performing resistance value measurement on each row of layout resistors in the resistor array in an reference state;
calculating a corresponding first mean value and a first standard deviation based on the resistance data of each row, wherein the first mean value and the first standard deviation represent the resistance value deviation;
obtaining a random number that conforms to Gaussian distribution by performing simulation based on a number of layout resistors in each row, the first mean value, and the first standard deviation; and
obtaining the simulated resistance value by assigning a value to the layout resistor based on the random number.

17. The electronic device according to claim 14, wherein constructing the performance model of the digital-to-analog converter based on the mapping relationship comprises:
constructing the performance model of the digital-to-analog converter based on the mapping relationship and a calculation model of a differential nonlinear error, wherein a performance parameter of the digital-to-analog converter comprises the differential nonlinear error.

18. A non-transitory computer-readable storage medium, wherein a computer program is stored on the non-transitory computer-readable storage medium, when the computer program is executed by a processor, a method for optimizing an arrangement of a resistor array is implemented, and the method comprises:
creating a corresponding resistor array based on a conversion circuit of a digital-to-analog converter;
establishing a mapping relationship between a layout resistor in the resistor array and a circuit resistor in the conversion circuit, wherein the layout resistor has a simulated resistance value, and the mapping relationship is used to determine a resistance value of the circuit resistor based on the layout resistor and the corresponding simulated resistance value;
constructing a performance model of the digital-to-analog converter based on the mapping relationship; and
performing iterative evolution on the mapping relationship based on the performance model until a target mapping relationship is obtained by evolution, wherein the target mapping relationship is used to determine a target arrangement of the layout resistor in the resistor array, to determine a target resistance value of the circuit resistor based on the target arrangement, and enable the performance model to output a target performance parameter based on the target resistance value.

19. The non-transitory computer-readable storage medium according to claim 18, wherein establishing the mapping relationship between the layout resistor in the resistor array and the circuit resistor in the conversion circuit comprises:
obtaining a circuit code by adding a first group of random codes to the circuit resistor;
obtaining a layout code by adding a second group of random codes to the layout resistor; and
establishing the mapping relationship based on a corresponding relationship between a single circuit resistor and at least one layout resistor, the circuit code and the layout code.

20. The non-transitory computer-readable storage medium according to claim 19, wherein performing iterative evolution on the mapping relationship based on the performance model until the target mapping relationship is obtained by evolution, comprises:
configuring, based on the circuit code and the layout code in the mapping relationship, a mapping sequence as a gene code, to configure a population based on a plurality of gene codes;
configuring a fitness function based on the performance model; and
performing, based on the fitness function, iterative evolution based on a genetic algorithm on the population, to continuously adjust an arrangement of the layout resistor in the resistor array until the target mapping relationship is obtained by evolution.
